(19) United States
(12) Patent Application Publication
(10) Pub. No.: US 2017/0181311 A1
(43) Pub. Date: Jun. 22, 2017

(54) MICROSERVER SYSTEM

(71) Applicants: Inventec (Pudong) Technology Corporation, Shanghai (CN); INVENTEC CORPORATION, Taipei City (TW)

(72) Inventor: Lan-Lan FANG, SHANGHAI (CN)

(21) Appl. No.: 15/371,227

(22) Filed: Dec. 7, 2016

(30) Foreign Application Priority Data
Dec. 16, 2015 (CN) 201510952984.8

(51) Int. Cl. H05K 7/14; H05K 7/20

(52) U.S. Cl. CPC H05K 7/1487; H05K 7/20836; H05K 7/20727

(57) ABSTRACT

Microserver system includes blade servers, a middle-plane board, a network-management board, and a main control module. Each of the blade servers includes a CPU board electrically connected to the middle-plane board. The network management board is electrically connected to the CPU boards through the middle-plane board, and the CPU boards can communicate with each others through the network management board. The main control module electrically connected to the middle-plane board includes a power-supply module and a system-management module. The power-supply module is electrically connected to the CPU boards and the network-management board through the middle-plane board. The system-management module respectively receives system-statue signals from the CPU boards through the middle-plane board, and the system-management module is configured to generate a power-supply controlling signal and a network-managing-board controlling signal, and transmit to the power-supply module and the network-management board respectively.

### RELATED APPLICATIONS

This application claims priority to Chinese Application Serial Number 201510952984.8, filed Dec. 16, 2015, which is herein incorporated by reference.

### BACKGROUND

Field of Invention

The present disclosure relates to a server system architecture design. More particularly, the present disclosure relates to a microserver system architecture design.

Description of Related Art

Degree of dependence of server systems is increased owing to various demands generating from increasing internet users under advancement of technology, consequently, demands on improving the computing capacity and the data storage capacity of commercial server systems are created. In favor of fulfilling the user's demands of the computing capacity and the data storage capacity on server systems, a quantity of system essential electronic components, such as servers, hard disk drives (HDDs), and other electronic components aiding the servers and the hard disk drives operating normally, such as a power supply, a fan module, or a network switching system, installed in a single server system should be correspondingly increased. Therefore, a space occupied by the server system is also increased for accommodating more electronic components. In order to improve a level of integration density on a server, a server system featuring with a high level of integration on the central processing units, such as a microserver featuring with a high level of integration on ARM(Advanced RISC Machine)-based microprocessors, has become a mainstream product in the market. However, the micro server featuring with a high level of integration is limited by design cost and limited space.

Consequently, a micro server system is hard to reasonably arrange motherboards, hard disk drives, multiple fans and other electronic components within a limited space of a housing, and allocate an optimum distribution of physical connections and electrical connections among electronic components at the same time. To deal with aforesaid problem, practitioners of ordinary skill in the art have striven to attain a novel system architecture design for a server, still lacks a suitable solution to be developed. Therefore, to deal with aforesaid problem effectively an important subject of research and development, and also a desired improvement in the art.

### SUMMARY

The present disclosure provides a microserver system. The microserver system includes a plurality of blade servers, a middle plane board, a network management board, and a main control module. Each of the blade servers includes a CPU (central processing unit) board. The middle plane board is electrically connected to the CPU boards. The network management board is electrically connected to the CPU boards through the middle plane board, in which the CPU boards communicate with each others through the network management board. The main control module is electrically connected to the middle plane board. The main control module includes a power supply module and a system management module. The power supply module is electrically connected to the CPU boards and the network management board through the middle plane board. The system management module respectively receives system statue signals from the CPU boards through the middle plane board, and the system management module generates a power-supply controlling signal and a network-managing-board controlling signal, and the power-supply controlling signal and the network-managing-board controlling signal are transmitted to the power supply module and the network management board respectively.

According to an embodiment of the present disclosure, each of the CPU boards may include two host system modules and a complex programmable logic device. The host system modules are electrically connected to each other for communicating through the complex programmable logic device.

According to an embodiment of the present disclosure, each of the host system modules may include a central processing unit, a platform controller hub, and a basic management controller. The platform controller hub is electrically connected to the central processing unit. The basic management controller is electrically connected to the central processing unit through the platform controller hub, and the basic management controller is electrically connected to the complex programmable logic device. The basic management controller and the complex programmable logic device collaboratively transmit a system controlling signal.

According to an embodiment of the present disclosure, each of the blade servers may further include a hard disk drive array. The hard disk drive array includes a back plane and hard disk drives. The back plane is electrically connected to the CPU board and the hard disk drives.

According to an embodiment of the present disclosure, each of the blade servers may further include a front panel disposed at a front end of the corresponding blade server. The front panel is electrically connected to the basic management controller, and the front panel includes a switch button and at least one operating statue indicating led.

According to an embodiment of the present disclosure, each of the blade servers may further include temperature sensors electrically connected to the basic management controllers of the host system modules. The temperature sensors monitor a working temperature of the corresponding blade server, and transmit a working temperature data to the basic management controllers of the host system modules. The basic management controllers transmit the system statue signal based on the working temperature data.

According to an embodiment of the present disclosure, the main control module may further include fan modules electrically connected to the middle plane board. The system management module transmits to the fan modules through the middle plane board according to the system statue signal. The system management module transmits the power-supply controlling signal to the power supply module for adjusting electrical power of the fan modules.

According to an embodiment of the present disclosure, the network management board may include high-speed network interfaces, a network switching module, and a network processing board. The high-speed network interfaces transmits a network signal. The network switching module is electrically connected to the high-speed network interfaces and the blade servers. The network switching module can transmit the network signal to the blade servers. The network processing board is electrically connected to the network switching module, and controlled the network switching module transmitting the network signal to the blade servers.

According to an embodiment of the present disclosure, the main control module may further include fan modules. The CPU boards and the fan modules are electrically connected to the middle plane board respectively. The CPU boards can transmit on-off signal to the system management module through the middle plane board for activating or deactivating the blade servers.

It is to be understood that both the foregoing general description and the following detailed description are by examples, and are intended to provide further explanation of the invention as claimed.

### BRIEF DESCRIPTION OF THE DRAWINGS

The disclosure can be more fully understood by reading the following detailed description of the embodiment, with reference made to the accompanying drawings as follows:

FIG. 1 is a structural block diagram of a microserver system according to an embodiment of the present disclosure.

FIG. 2 is a schematic longitudinal sectional view of a blade server according to another embodiment of the present disclosure.

FIG. 3 is a schematic front view of a blade server according to an embodiment of the present disclosure.

FIG. 4 is a three-dimensional perspective view of a microserver system according to an embodiment of the present disclosure.

FIG. 5 is a simplified schematic drawing of a first surface of a middle plane board on a microserver according to an embodiment of the present disclosure.

FIG. 6 is a simplified schematic drawing of a second surface of a middle plane board on a microserver according to an embodiment of the present disclosure.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

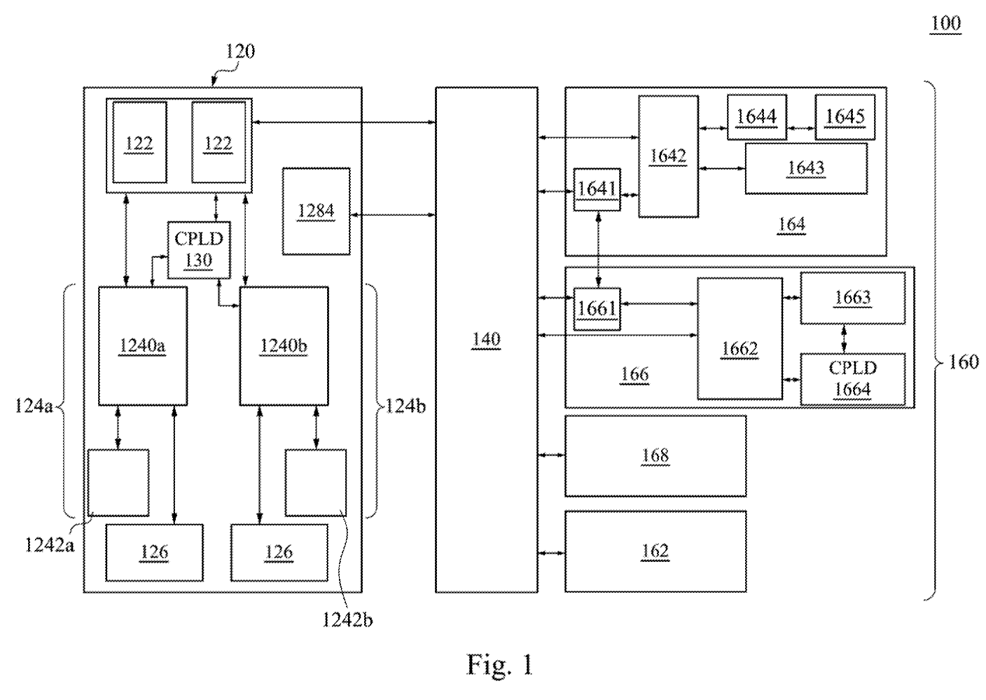

FIG. 1 illustrates a structural block diagram of a microserver system 100 according to an embodiment of the present disclosure. As shown in FIG. 1, microserver system 100 includes a plurality of blade servers 120, a middle plane board 140, a network management board 164, and a main control module 160. In some embodiments, each of the blade servers 120 may include a CPU (central processing unit) board. The CPU board, described herein, may include a basic management controller 122, host system modules 124a, 124b, a hard disk drive array 126, and a complex programmable logic device 130 . . . etc, which is not intended to limit the electronic components composed the CPU board. In some embodiments, the middle plane board 140 can be electrically connected to the blade servers 120 and the basic management controller 122 of the CPU boards. The network management board 164 is electrically connected to the CPU boards of the blade server 120 through the middle plane board 140, such that each of the CPU boards of blade servers 120 can communicate with the network management board 164, and also each of the CPU boards of blade servers 120 can also communicate with other CPU boards of blade servers 120 through the network management board 164.

In some embodiments, the main control module 160 can be electrically connected to the middle plane board 140. The main control module 160 includes power supply modules 162 and a system management module 166. The power supply module 162 is electrically connected to the CPU boards and the network management board 164 through the middle plane board 140.

In some embodiments, the CPU boards can transmit on-off signal to the system management module 166 through the middle plane board 140, the on-off signal can be used to activate or deactivate the blade servers 120.

In some embodiments, the system management module 166 receives a power supply from the power supply modules 162, and system statue signal from each of the basic management controllers 122 on the CPU boards through the middle plane board 140. In some embodiments, the system management module 166 generates a power-supply controlling signal, and transmit the power-supply controlling signal to the power supply modules 162, such that the power-supply controlling signal is used to control the power supply modules 162 providing power to other electronic components of the microserver system 120, such as blade servers 120, the network management board 164, and the main control module 160 . . . etc. In some embodiments, the power supply modules 162 may include backup power supply module. In some embodiments, the power-supply controlling signal may include signals, such as SCL/SDA lines of I2C (Inter-Integrated Circuit) interface, power supply on-off signal, power supply input monitoring signal, power supply present signal, and power supply input signal . . . etc.

In some embodiments, the system management module 166 is configured to generate a network-managing-board controlling signal, and transmit the network-managing-board controlling signal to the network management board 164. In some embodiments, the network-managing-board controlling signal may include signals, such as SCL/SDA lines of I2C interface or CLK/LD/DIN/DO signal of SGPIO (serial general purpose input/output) interface. In some embodiments, the main control module 160 further includes fan modules 168, the fan modules 168 are electrically connected to the middle plane board 140.

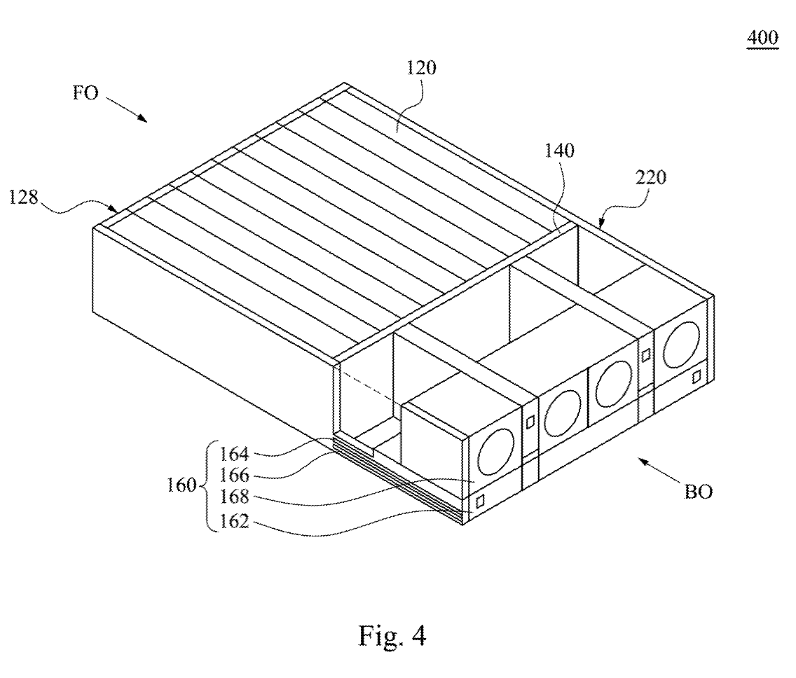

Due to the microserver system 100 assembles the blade servers 120 under a system architecture design of microserver, the electronic components used to aid the blade servers 120 operating normally, such as the power supply modules 162, the network management board 164, the system management module 166, the fan modules 168 . . . etc., are integrated into the main control module 160. Therefore, a space occupied by the electronic components can be further reduced. Besides, the microserver system 100 adopts the middle plane board 140 to electrically connect the blade servers 120 and the electronic components of the main control module 160 individually, so that the complex interconnecting relation among the electronic components of the main control module 160 is simplified, and furthermore, the complexity of interconnecting relation among the blade servers 120 and the electronic components can be efficiently reduced. In the meanwhile, due to the blade servers 120 and the electronic components of the main control module 160 are inserted into connecters installed on an integrated surface of the middle plane board 140, and interconnected to each others through pins instead of arranging a layout of cables. Therefore, the arrangement of the connection layout can be optimized through the middle plane board 140 to release a space within the housing 220 (as shown in FIG. 4), and the complex layout of physical connections and circuit connections can also be simplified through the middle plane board 140.

In addition, due to both the network management board 164 and the system management module 166 transmit signal through the middle plane board 140, a remote user can connect to the network management board 164 and the system management module 166 to transmit related system control signal, and the system control signals can be transmitted to electronic components of the microserver system 100. Therefore, controlling and management of the operation on the blade server 120 and the main control module 160 can be simplified and remote controlled.

In some embodiments, each of the CPU boards of blade server 120 may include two host system modules 124a, 124b and a complex programmable logic device 130(CPLD). The complex programmable logic device 130 is electrically connected between the host system modules 124a, 124b. The host system modules 124a, 124b can communicate with each other through the complex programmable logic device 130. It should be understood that, the complex programmable logic device 130, described above, is only an exemplary, and not intended to limit the present disclosure, could be adjusted to actual demand by those skilled in the art. In some embodiments, the basic management controllers 122 can be electrically connected to the complex programmable logic device 130.

In some embodiments, the host system modules 124a, 124b respectively includes the basic management controllers 122, the platform controller hub s 1240a, 1240b and central processing units 1242a, 1242b. In some embodiments, the basic management controllers 122 are electrically connected to the central processing units 1242a, 1242b through the platform controller hub s1240a, 1240b respectively, and also electrically connected to the complex programmable logic device 130. The basic management controllers 122 130 can transmit a system controlling signal with the complex programmable logic device for controlling the operation of the host system modules 124a, 124b. In some embodiments, the platform controller hub s 1240a, 1240b can be Skylake PCH-H or other suitable platform controller hub. In some embodiments, the central processing units 1242a, 1242b can be Xeon E3-1200 v5 or other suitable central processing unit. In some embodiments, the host system modules 124a, 124b can be a host system module constructed under the Greenlow architecture design. In some embodiments, the system statue signal can be transmitted through I2C interface or SGPIO interface. The central processing units 1242a, 1242b can be electrically connected to the platform controller hub s 1240a, 1240b correspondingly. In some embodiments, the central processing units 1242a, 1242b are individually connected to DRAMs (Dynamic random access memory). Due to each of the blade servers 120 is installed with two host system modules 124a, 124b, the microserver system 100 of the present disclosure may have a greater level of integration.

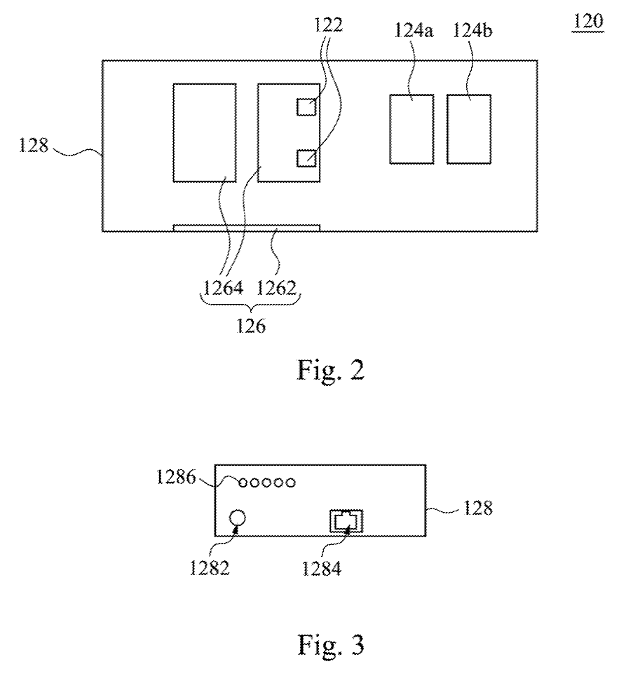

FIG. 2 illustrates a schematic longitudinal sectional view of a blade server 120 according to an embodiment of the present disclosure. As shown in FIG. 2, in some embodiments, each of the blade servers 120 may further include a hard disk drive array 126. The hard disk drive array 126 includes a back plane 1262 and hard disk drives 1264. The back plane 1262 is electrically connected to the corresponded platform controller hubs 1240a, 1240b of the CPU board and the hard disk drive array 126. In some embodiments, each of the hard disk drive array 126 may be electrically connected to the four SATA (serial advanced technology attachment) hard disk drives 1264. In some embodiments, each of the hard disk drive array 126 may be electrically connected to the six SATA hard disk drives 1264. In some embodiments, the basic management controllers 122 can be disposed proximal to the hard disk drives 1264.

FIG. 3 is a schematic front view of a blade server 120 according to an embodiment of the present disclosure. As shown in FIG. 3, in some embodiments, the blade server 120 may further include a front panel 128, disposed at a front end of the blade server 120. The front panel 128 is electrically connected to the basic management controller 122. The front panel 128 may include a switch button 1282, a controller connector 1284 and at least one operating statue indicating led 1286. In some embodiments, each of the switch buttons 1282 can respectively control the blade servers 120 being activated or deactivated. In some embodiments, the controller connector 1284 can be a RJ(Registered Jack)-45 connector. In some embodiments, the front panel 128 may further include a media port, such as USB (universal serial bus) . . . etc. In some embodiments, the network management board 164 include a media port 1641 (referring to FIG. 1) electrically connected to the controller connector 1284. The network management board 164 transmits the system controlling signal to the basic management controller 122 through the controller connector 1284, and adjusts a controller configuration of the basic management controller 122. In some embodiments, the controller connector 1284 can transmit the system controlling signal to the basic management controller 122 through SGMII (serial gigabit media independent interface) . . . etc. In some embodiments, the operating statue indicating led 1286 may display light with different colors, to make the user acknowledge an operating statue of the blade server 120 within the microserver system 100.

Referring to FIG. 2, in some embodiments, the basic management controller 122 is disposed inside the blade server 120, which monitors a system statue of the blade server 120. The basic management controller 122 generates a system statue signal according to the system statue, and the system statue signal is transmitted to the system management module 166. In some embodiments, the system statue signal includes SCL/SDA lines of I2C interface or CLK/LD/DIN/DO signal of SGPIO interface . . . etc. The system management module 166 transmits the power-supply controlling signal to the power supply module 162 and the network-managing-board controlling signal to the network management board 164 based on the system statue signal.

In some embodiments, the blade server 120 further includes temperature sensors disposed inside the blade servers 120. The temperature sensors are electrically connected to the corresponding basic management controllers 122 of the host system modules 124a, 124b, and monitor a working temperature of the corresponding blade server 120. Subsequently, the temperature sensors transmit a working temperature data to the basic management controllers 122 of the host system modules 124a, 124b based on the working temperature data of the blade server 120, and then the basic management controllers 122 can transmit the system statue signal based on the working temperature data.

In some embodiments, the fan modules are electrically connected to the middle plane board 140, and the CPU board and the fan modules are electrically connected to the middle plane board 140 respectively. In some embodiments, the fan modules 168 may include a backup fan module. The system management module 166 can generate a fan controlling signal based on the system statue signal, and transmit to the fan modules 168 through the middle plane board 140. In the meanwhile, the system management module 166 can transmit the power-supply controlling signal to the power supply module 162, to adjust electrical power provided to the fan modules 168. Therefore, the system management module 166 can control the working temperature of the blade servers 120 and the microserver system 100. In some embodiments, the system management module 166 can transmit a fan insert-checking signal to the fan modules 168 for monitoring an insert statue of the fan modules 168.

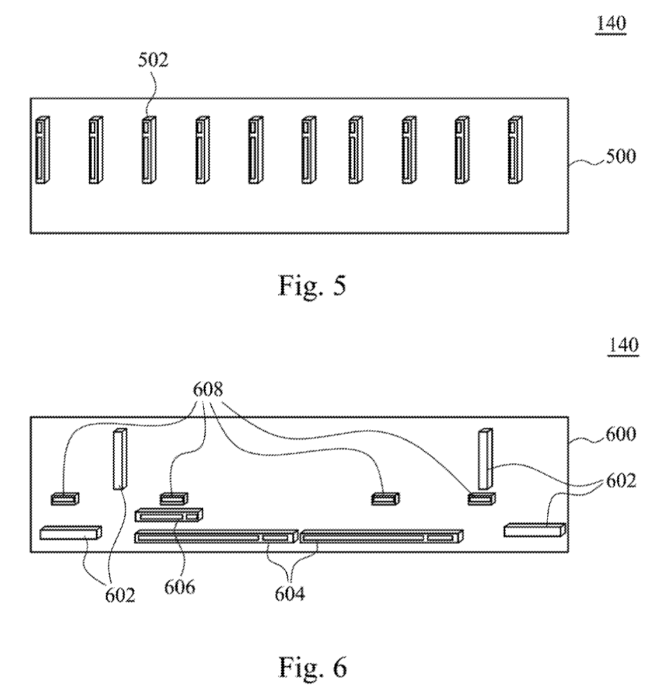

FIG. 4 illustrates a three-dimensional perspective view of a microserver system 400 according to an embodiment of the present disclosure. FIG. 5 illustrates a simplified schematic drawing of a first surface 500 of a middle plane board 140 on a microserver 400 according to an embodiment of the present disclosure. FIG. 6 illustrates a simplified schematic drawing of a second surface 600 of a middle plane board 140 on a microserver 400 according to an embodiment of the present disclosure.

As shown in FIG. 4, the microserver 400 may further include a housing 220 defining an accommodation space. The housing 220 has a front opening FO and a back opening BO opposite to the front opening FO. Each of the blade servers 120 is at least a part being disposed within the accommodation space and proximal to the front opening FO. In some embodiment, the front panel 128 is located inside the accommodation space. In other embodiments, the front panel 128 is located outside the accommodation space. The middle plane board 140 is disposed within the accommodation space, and located between the blade servers 120 and the main control module 160.

Referring to FIG. 5 and FIG. 6, the middle plane board 140 has the first surface 500 and the second surface 600 opposite to the first surface 500. The first surface 500 abuts against an end of each of the blade servers. The first surface 500 includes first connectors 502 configured to dock the blade servers 120 respectively. In some embodiments, the blade server 120 includes golden finger, the golden finger include board-managing-controller pins and power-supply pins, in which the board-managing-controller pins are connected to the basic management controllers 122 correspondingly. In some embodiments, the golden finger is docked to the middle plane board 140, the board-managing-controller pins and power-supply pins are electrically connected to the first connector 502.

In some embodiments, the main control module 160 is disposed within the accommodation space and proximal to the back opening BO, and abuts against the second surface 600. The second surface 600 includes second connectors electrically connected to the corresponded main control module 160. In some embodiments, the second connectors may include power-supply connectors 602, a network-managing-board connector 604, a system-manager-module connector 606 and fan-module connectors 608 for docking the power supply modules 162, the network management board 164, the system management module 166, and the fan modules 168 respectively. In some embodiments, the first connectors 502 are correspondingly connected to the main control module 160 through the second connector.

Referring back to FIG. 1, in some embodiments, the network management board 164 may include a network switching module 1642, high-speed network interfaces 1643(a single high-speed network interface 1643 is drawn in FIG. 1 as an exemplary), and a network processing board 1644. In some embodiments, the high-speed network interfaces are configured to transmit a network signal from internet. The network switching module 1642 is electrically connected to the high-speed network interfaces 1643 and the blade servers 120 separately, and the network switching module 1642 can transmit the network signal to the blade servers 120. In other word, the high-speed network interfaces 1643 is electrically connected to the network switching module 1642, and the high-speed network interfaces 1643 transmit the network signal from the blade servers 120 through the network switching module 1642.

In some embodiments, the network switching module 1642 is coupled to the middle plane board 140 through SerDes (serializer/deserializer) interfaces, and the blade servers 120 are also coupled to the middle plane board 140 through SerDes interfaces. In some embodiments, the SerDes interface may include SATA, SAS (serial attached SCSI), USB2.0/3.0, PCIE (peripheral component interconnect express) interface, HDMI (high definition multimedia interface), XAUI (10 gigabit media independent interface), fiber-optical communication interface or other suitable interface. In some embodiments, the high-speed network interfaces 1643 can be a small form-factor pluggable transceiver (SFP) configured to connect to an optical network. In some embodiments, the network processing board 1644 includes a network switching processor 1645. The network processing board 1644 is electrically connected to the network switching module 1642. The network processing board 1644 can control the network switching module 1642 transmitting/receiving the network signal to the blade servers 120 through the network switching processor 1645.

In some embodiments, the network management board 164 may further include network ports 1641 electrically connected to the middle plane board 140. In some embodiments, the network ports 1641 can be electrically connected to the basic management controllers 122 through the middle plane board 140. A remote user can connect to the basic management controllers 122 through the network ports 1641, to monitor and control the microserver system 100. In some embodiments, the network ports 1641 can be electrically connected to the basic management controllers 122 through the SGMII or other suitable interface.

In some embodiments, the system management module 166 may include a system manager daughter board 1662 and a system manager processor 1663. The system manager daughter board 1662 is electrically connected to the middle plane board 140. In some embodiments, the system manager daughter board 1662 can be electrically connected to the middle plane board 140 through I2C interface, buses, SGPIO interface, GPIO interface or other suitable interface. The system manager processor 1663 electrically connected to the system manager daughter board 1662 can be used to generate and transmit the power-supply controlling signal and the network-managing-board controlling signal based on the system statue signal. In some embodiments, the system management module 166 may further include a complex programmable logic device 1664. The complex programmable logic device 1664 can receive the system statue signal and control the system manager processor 1663 transmitting the power-supply controlling signal and the network-managing-board controlling signal. In some embodiments, the system management module 166 may further include a network port 1661 electrically connected to the middle plane board 140. A remote user can communicate with network port 1661 through the network ports 1641, to monitor and control the system management module 166 through the network ports 1661.

Due to a remote user can control the network management board 164 and the system management module 166 to transmit the microserver system control signal, such as the power-supply controlling signal and the network-managing-board controlling signal . . . etc., through the network ports 1641 and the network ports 1661. The microserver system control signal can be transmitted to electronic components of the microserver system 100. Therefore, the remote user can manage the operation of the blade servers 120 and other electronic components of the main control module 160, such as the power supply modules 162, the network management board 164, the system management module 166, and the fan modules 168, the through internet, to achieve demand of remote control.

Summarized from the above, the present disclosure provides a microserver system including a plurality of blade servers, a middle plane board, a network management board, and a main control module. The blade servers and the main control module are integrated in a system architecture design of microserver, and electronic components, such as power supplies, fan modules, network management board, and the system management module, are integrated into the main control module. Therefore, a space occupied by the electronic components of the microserver system can be reduced. In addition, both the blade servers and the main control module are installed on the middle plane board, and then the microserver system integrates physical connections and circuit connections intervening among the blade servers and the main control module into a fixed plane, such as the middle plane board. A space of the housing can be released to accommodate more electronic components, and the microserver system may feature with an optimized conduct routes arrangement, to avoid or prevent conduct routes of the micro server system interfering with each others.

Although some embodiments of the present disclosure and their advantages have been described in detail, it should be understood that various changes, substitutions, and alterations can be made herein without departing from the spirit and scope of the disclosure as defined by the appended claims. For example, it will be readily understood by those skilled in the art that many of the features, functions, processes, and materials described herein may be varied while remaining within the scope of the present disclosure. Moreover, the scope of the present application is not intended to be limited to the particular embodiments of the process, machine, fabricate, composition of matter, means, methods, and steps described in the specification. As one of ordinary skill in the art will readily appreciate from the disclosure of the present disclosure, processes, machines, fabricate, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, fabricate, compositions of matter, means, methods, or steps.

What is claimed is:

1. A microserver system, comprising:
a plurality of blade servers, each of the blade servers comprising a CPU board;
a middle plane board electrically connected to the CPU boards;
a network management board electrically connected to the CPU boards through the middle plane board, wherein the CPU boards communicate with the network management board; and
a main control module electrically connected to the middle plane board, and the main control module comprising:
a power supply module electrically connected to the CPU boards and the network management board through the middle plane board; and
a system management module receiving system statue signals from the CPU boards through the middle plane board, and the system management module generating a power-supply controlling signal and a network controlling signal, and the power-supply controlling signal and the network controlling signal being transmitted to the power supply module and the network management board respectively.

2. The microserver system of claim 1, wherein each of the CPU boards comprises two host system modules and a complex programmable logic device, the host system modules are electrically connected to each other for communicating through the complex programmable logic device.

3. The microserver system of claim 2, wherein each of the host system modules comprises:
a central processing unit;
a platform controller hub electrically connected to the central processing unit; and
a basic management controller electrically connected to the central processing unit through the platform controller hub, and the basic management controller being electrically connected to the complex programmable logic device, the basic management controller transmitting a system controlling signal with the complex programmable logic device collaboratively.

4. The microserver system of claim 3, herein each of the blade servers further comprises a hard disk drive array, the hard disk drive array comprises a back plane and a plurality of hard disk drives, and the back plane is electrically connected to the CPU board and the hard disk drives.

5. The microserver system of claim 4, wherein each of the blade servers further comprises a front panel disposed at a front end of the corresponding blade server, the front panel is electrically connected to the basic management controller, and the front panel comprises a switch button and at least one operating statue indicating led.

6. The microserver system of claim 3, wherein each of the blade servers further comprises a plurality of temperature sensors electrically connected to the basic management controllers of the host system modules, the temperature sensors monitor a working temperature of the corresponding blade server, and transmit a working temperature data to the basic management controllers of the host system modules, the basic management controllers transmit the system statue signal based on the working temperature data.

7. The microserver system of claim 6, wherein the main control module further comprises a plurality of fan modules electrically connected to the middle plane board, the system management module generates a based on the system statue signal, and transmits fan controlling signal to the fan modules through the middle plane board according to the system statue signal, and the system management module transmits the power-supply controlling signal to the power supply module for adjusting electrical power of the fan modules.

8. The microserver system of claim 1, wherein the network management board comprises:
a plurality of high-speed network interfaces transmitting a network signal;
a network switching module electrically connected to the high-speed network interfaces and the blade servers, the network switching module transmits the network signal to the blade servers; and
a network processing board electrically connected to the network switching module, and controlled the network switching module transmitting the network signal to the blade servers.

9. The microserver system of claim 1, wherein the main control module further comprises a plurality of fan modules, the CPU boards and the fan modules electrically connected to the middle plane board respectively, the CPU boards transmit on-off signal to the system management module through the middle plane board for activating or deactivating the blade servers.
